(19) United States
(12) Patent Application Publication
(10) Pub. No.: US 2026/0269828 A1
(43) Pub. Date: Sep. 10, 2026

(54) SENSOR DEVICE AND STEERING DEVICE

(71) Applicant: ALPS ALPINE CO., LTD., Tokyo (JP)

(72) Inventors: Kazuma HORIE, Miyagi (JP); Takeshi MASAKI, Miyagi (JP)

(21) Appl. No.: 19/664,103

(22) Filed: Apr. 30, 2026

Related U.S. Application Data
(63) Continuation of application No. PCT/JP2024/039323, filed on Nov. 5, 2024.

(30) Foreign Application Priority Data
Dec. 28, 2023 (JP) 2023-222685

(51) Int. Cl. H03K 17/96; B62D 1/04; B62D 1/08

(52) U.S. Cl. CPC H03K 17/962; B62D 1/046; B62D 1/08; H03K 2217/960755

(57) ABSTRACT

A sensor device includes a housing, a detection electrode provided on an outer peripheral surface of the housing so as to face a rim portion and configured to detect a capacitance by being capacitively coupled with a hand of a driver gripping the rim portion, an operation knob having an operation surface exposed through an opening of a decorative cover and arranged in such a manner that the operation surface faces the driver, a substrate provided in an interior space of the housing, and an operation input detector provided on the substrate and configured to detect an operation input by the driver via the operation knob. The housing includes a regulating wall configured to control water that has entered from the periphery of the operation knob in the opening of the decorative cover.

### CROSS-REFERENCE TO RELATED APPLICATIONS

This application is a continuation application of International Application No. PCT/JP2024/039323 filed on Nov. 5, 2024, and designating the U.S., which is based upon and claims priority to Japanese Patent Application No. 2023-222685 filed on Dec. 28, 2023, the entire contents of which are incorporated herein by reference.

### BACKGROUND

### 1. Technical Field

The present invention relates to a sensor device and a steering device.

### 2. Description of Related Art

Japanese Unexamined Patent Application Publication No. 2023-063050 (hereinafter “Patent Document 1”) cited below discloses a technology for detecting contact of an occupant's hand with a portion of a rim that is connected to a spoke, using an electrode arranged in the spoke of a steering wheel that is equipped with a switch in the spoke.

### SUMMARY

A sensor device according to an embodiment is to be mounted in a spoke portion of a steering wheel and to be covered with a decorative cover having an opening, the steering wheel including a rim portion for a driver to grip, a hub portion arranged at a center of the rim portion, and the spoke portion extending from the hub portion and supporting the rim portion. The sensor device includes a detection electrode provided on an outer peripheral surface of the housing so as to face the rim portion and configured to detect a capacitance by being capacitively coupled with a hand of the driver gripping the rim portion; an operation knob having an operation surface exposed through the opening of the decorative cover and arranged in such a manner that the operation surface faces the driver; a substrate provided in an interior space of the housing; and an operation input detector provided on the substrate and configured to detect an operation input by the driver via the operation knob. The housing includes a regulating wall configured to control, when the sensor device is exposed to water, water that has entered from the periphery of the operation knob in the opening of the decorative cover so as not to reach both the detection electrode and the substrate in both a case where the steering wheel is in an initial state and a case where the steering wheel is rotated in any direction.

### BRIEF DESCRIPTION OF THE DRAWINGS

FIG. 1 is a plan view of a steering device according to an embodiment;

FIG. 2 is a schematic cross-sectional view of the steering device according to the embodiment;

FIG. 3 is an enlarged view of a peripheral portion of a sensor device in the steering device according to the embodiment, shown with a decorative cover not attached;

FIG. 4 is an enlarged view of the peripheral portion of the sensor device in the steering device according to the embodiment, shown with a decorative cover attached;

FIG. 5 is an external perspective view of the sensor device according to the embodiment;

FIG. 6 is an exploded perspective view of the sensor device according to the embodiment;

FIG. 7 is a cross-sectional view schematically illustrating a stack structure of an electrostatic detector included in the sensor device according to the embodiment;

FIG. 8 is a diagram illustrating a configuration of a control system included in the sensor device according to the embodiment;

FIG. 9 is a partially enlarged perspective view of the sensor device according to the embodiment;

FIG. 10 is a partially enlarged perspective view of the sensor device according to the embodiment as viewed from the driver side;

FIG. 11 is a partially enlarged perspective view of the sensor device according to the embodiment, shown with a plurality of operation knobs removed;

FIG. 12 is a plan view of the sensor device according to the embodiment as viewed from the driver side;

FIG. 13 is a diagram illustrating a drainage path in the sensor device when a steering wheel is in its initial state;

FIG. 14 is a diagram illustrating the drainage path in the sensor device when the steering wheel is rotated 90 degrees clockwise;

FIG. 15 is a diagram illustrating the drainage path in the sensor device when the steering wheel is rotated 180 degrees clockwise; and

FIG. 16 is a diagram illustrating the drainage path in the sensor device when the steering wheel is rotated 270 degrees clockwise.

### DETAILED DESCRIPTION

However, in the technology disclosed in Patent Document 1, when the spoke of the steering wheel is exposed to water, water that has entered from the periphery of the switch can reach the electrode and capacitively couples with the electrode, which may hinder the electrode from accurately detecting contact by an occupant's hand.

In the steering wheel disclosed in Patent Document 1, when a substrate on which a detection means for detecting operation of the switch is mounted is arranged on the rear side of the switch, water that has entered from the periphery of the switch can reach the substrate, which may hinder the detection means mounted on the substrate from accurately detecting operation of the switch.

According to the sensor device of an embodiment, when the sensor device is exposed to water, water that has entered from the periphery of the operation knobs can be prevented from reaching both the detection electrode and the substrate.

Hereinafter, an embodiment will be described with reference to the drawings.

### Configuration of Steering Device 10

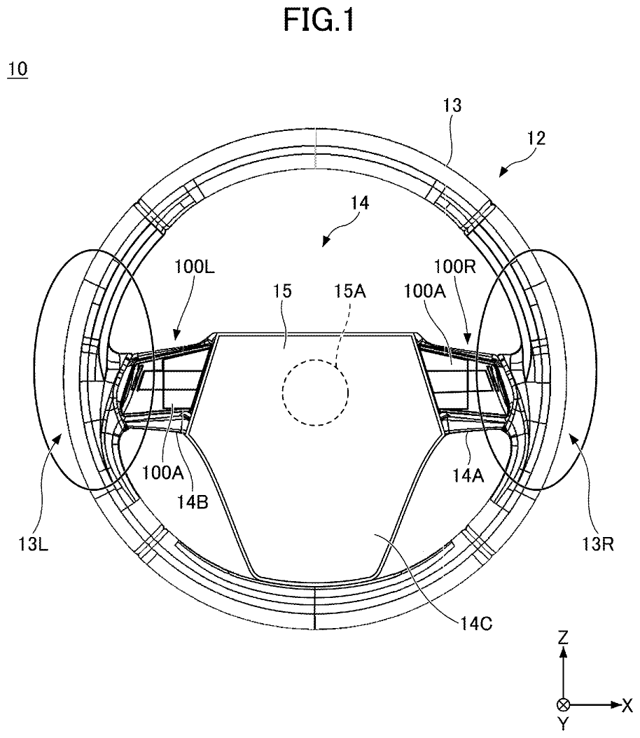

FIG. 1 is a plan view of a steering device 10 according to the present embodiment.

In the following description, for the sake of convenience, the X-axis direction is set to the left-right direction, the Y-axis direction is set to the front-rear direction, and the Z-axis direction is set to the up-down direction. However, the positive X-axis direction is set to the right direction, the positive Y-axis direction is set to the front direction, and the positive Z-axis direction is set to the upward direction. These are intended to indicate the relative positional relationship within the device, and are not intended to limit the installation direction or operation direction of the device. All devices having the same relative positional relationship within the device are included within the scope of the present invention, even if the installation direction or operation direction is different.

The steering device 10 illustrated in FIG. 1 is installed in the cabin of a vehicle, such as an automobile, and enables the driver to operate the steering wheel and perform various input functions of the vehicle.

As illustrated in FIG. 1, the steering device 10 includes a steering wheel 12 and two sensor devices 100 (sensor devices 100L and 100R).

The steering wheel 12 includes a rim portion 13, a spoke portion 14, and a hub portion 15. The rim portion 13 is an annular portion which is engaged by the fingers of the driver's hand to operate the steering wheel. Although illustration is omitted, a cross-sectional configuration of the rim portion 13 includes a rim core portion made of a metal and arranged at the center of the rim portion 13 and a covering portion made of a resin (e.g., urethane) and covering the outer surface of the rim core portion. The left-side (negative X-axis side) area of the rim portion 13 serves as a grip portion 13L engaged by the fingers of the driver's left hand. The right-side (positive X-axis side) area of the rim portion 13 serves as a grip portion 13R engaged by the fingers of the driver's right hand. Although both the steering wheel 12 and the rim portion 13 of the present embodiment are in an annular shape, the present invention is not limited to this, and may have various shapes, such as a shape in which only the lower portion is connected and the upper portion is cut off, or a part of the rim is linear.

The hub portion 15 is provided in the center of the rim portion 13 and supports the spoke portion 14. The spoke portion 14 extends from the hub portion 15 in the outer radial direction of the rim portion 13 and supports the rim portion 13 from a radially inner side. In the present embodiment, as an example, the spoke portion 14 includes a first portion 14A extending rightward (positive X-axis direction) from the hub portion 15, a second portion 14B extending leftward (negative X-axis direction) from the hub portion 15, and a third portion 14C extending downward (negative Z-axis direction) from the hub portion 15. In other words, the spoke portion 14 has a substantially T-shape in a plan view.

The right (positive X-axis side) end portion of the first portion 14A of the spoke portion 14 is connected to the rim core portion of the rim portion 13 in the grip portion 13R area. The left (negative side of the X-axis) end portion of the second portion 14B of the spoke portion 14 is connected to the rim core portion of the rim portion 13 in the grip portion 13L area. The lower (negative Z-axis side) end of the third portion 14C of the spoke portion 14 is connected to the rim core portion of the rim portion 13. Thus, the spoke portion 14 supports the rim portion 13 from a radially inner side.

The spoke portion 14 and the hub portion 15 are composed of a spoke core portion made of a metal and serving as a base portion of the spoke portion 14, a hub core portion made of a metal and serving as a base portion of the hub portion 15, a covering portion made of a resin (e.g., urethane) and covering the outer surfaces of the spoke core portion and the hub core portion, and functional components, such as a decorative cover 16, which is made of a resin and attached to the driver side surfaces of the spoke core portion and the hub core portion, and a horn.

The hub portion 15 includes a through-hole 15A formed in the hub core portion, and is fixed to a steering shaft (not illustrated) inserted into the through-hole 15A by a nut (not illustrated) or the like. Thus, the hub portion 15 rotates together with the steering wheel 12 in accordance with a steering wheel operation, and the steering shaft can be rotated about the axis of the central axis.

The sensor devices 100L and 100R are installed in the spoke portion 14 to receive various operations that are input by the driver. The sensor device 100R is installed in the first portion 14A of the spoke portion 14. The sensor device 100L is installed in the second portion 14B of the spoke portion 14. The sensor devices 100L and 100R are substantially rectangular in a plan view from the driver side (negative Y-axis side), and are symmetrical with respect to a plane passing through the center of the steering wheel 12. The surfaces of the sensor devices 100L and 100R on the driver side (negative Y-axis side) are operation surfaces 100A with which the driver inputs various operations.

The sensor device 100L is provided in the vicinity of the grip portion 13L of the rim portion 13. The sensor device 100L can receive input on the operation surface 100A from the fingers of the driver's left hand engaging the grip portion 13L area. The sensor device 100L can detect, in a non-contact manner, the gripping state of the grip portion 13L by the driver's left hand.

The sensor device 100R is provided in the vicinity of the grip portion 13R of the rim portion 13. The sensor device 100R can receive input on the operation surface 100A from the fingers of the driver's right hand engaging the grip portion 13R area. The sensor device 100R can detect, in a non-contact manner, the gripping state of the grip portion 13R by the driver's right hand.

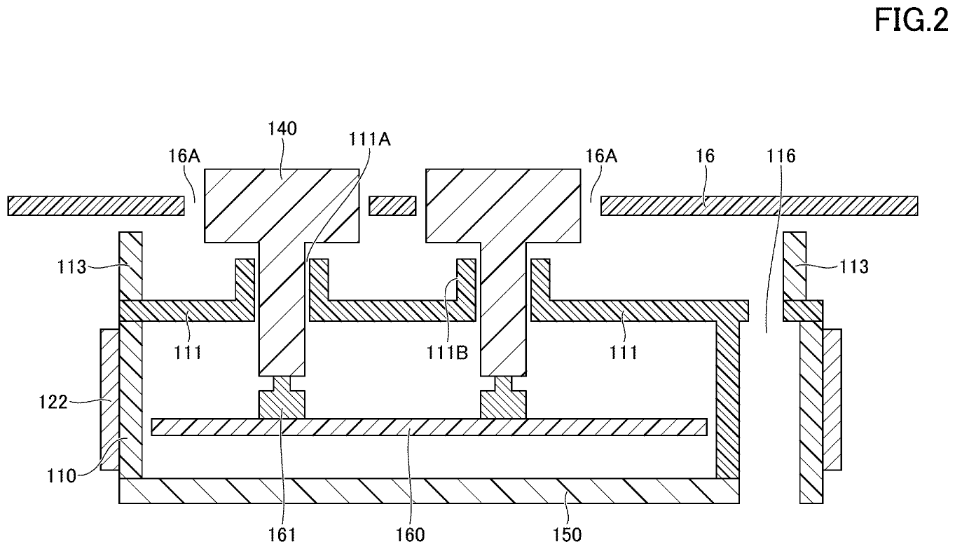

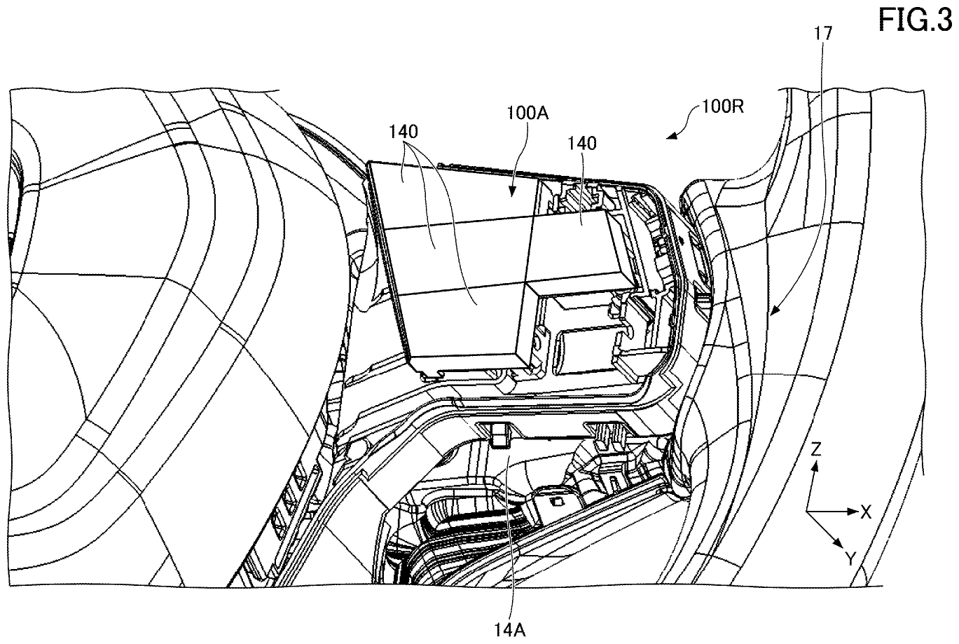

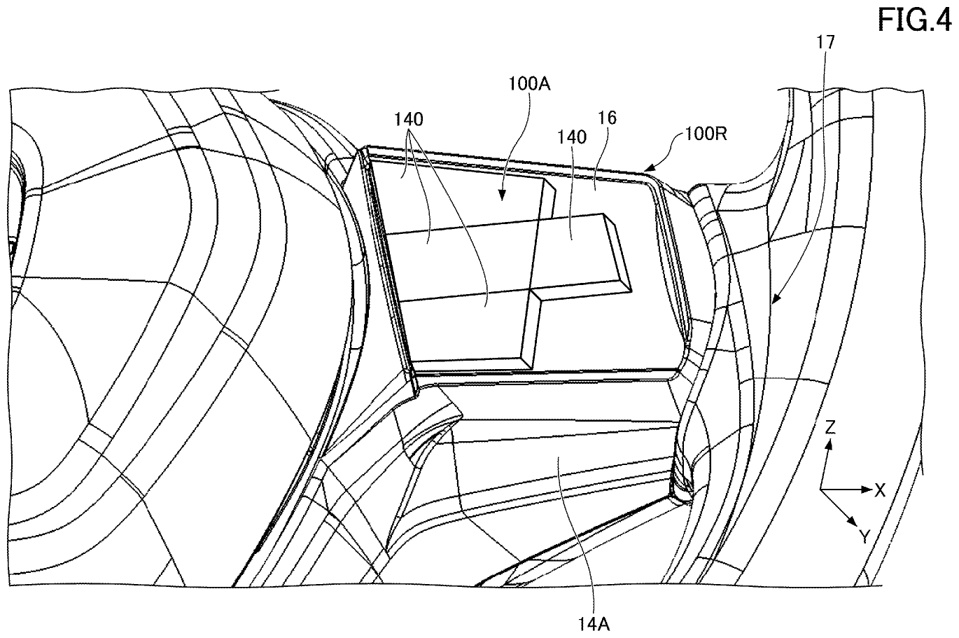

FIG. 2 is a schematic cross-sectional view of the sensor device 100R in the steering device 10 according to the present embodiment. FIG. 3 is an enlarged view of a peripheral portion of the sensor device 100R in the steering device 10 according to the present embodiment, shown with the decorative cover 16 not attached. FIG. 4 is an enlarged view of a peripheral portion of the sensor device 100R in the steering device 10 according to an embodiment, shown with the decorative cover 16 attached.

As illustrated in FIG. 3, the sensor device 100R is provided with a plurality of operation knobs 140 aligned on the operation surface 100A, which is a surface on the driver side. The sensor device 100R is installed in the first portion 14A of the spoke portion 14 of the steering wheel 12. As illustrated in FIG. 4, the decorative cover 16 made of a resin is attached to the driver side of the spoke portion 14 of the steering wheel 12. Thus, as illustrated in FIGS. 2 and 4, the sensor device 100R is mounted in the first portion 14A of the spoke portion 14 of the steering wheel 12 in a state where the plurality of operation knobs 140 are exposed through an opening 16A provided in the decorative cover 16 and the driver side is covered with the decorative cover 16. As a result, the operation surface 100A having a planar shape is formed on the driver side of the sensor device 100R together with the surface of the decorative cover 16 and the surfaces of the plurality of operation knobs 140.

As described above, the decorative cover 16 is formed with the opening 16A shaped to follow the outer contours of the plurality of operation knobs 140, as viewed from the driver side. As illustrated in FIGS. 2 and 4, the plurality of operation knobs 140 provided in the sensor device 100R are exposed through the opening 16A formed in the decorative cover 16, allowing operation from the driver side. In the present embodiment, an operation input is performed by a pressing action, but the input method is not limited to this, and other operation inputs, such as a tilting action, may be employed.

A slight gap is formed around the plurality of operation knobs 140 in the opening 16A. For this reason, in the steering device 10 according to the present embodiment, when the decorative cover 16 is exposed to water, water may enter from around the plurality of operation knobs 140 in the opening 16A and flow to the rear side of the decorative cover 16.

### Configuration of Sensor Device 100

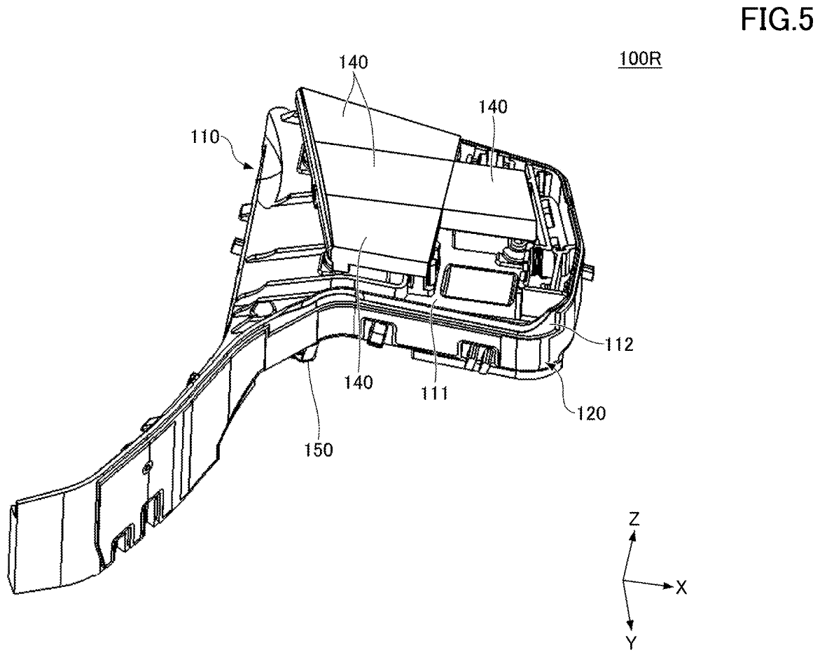

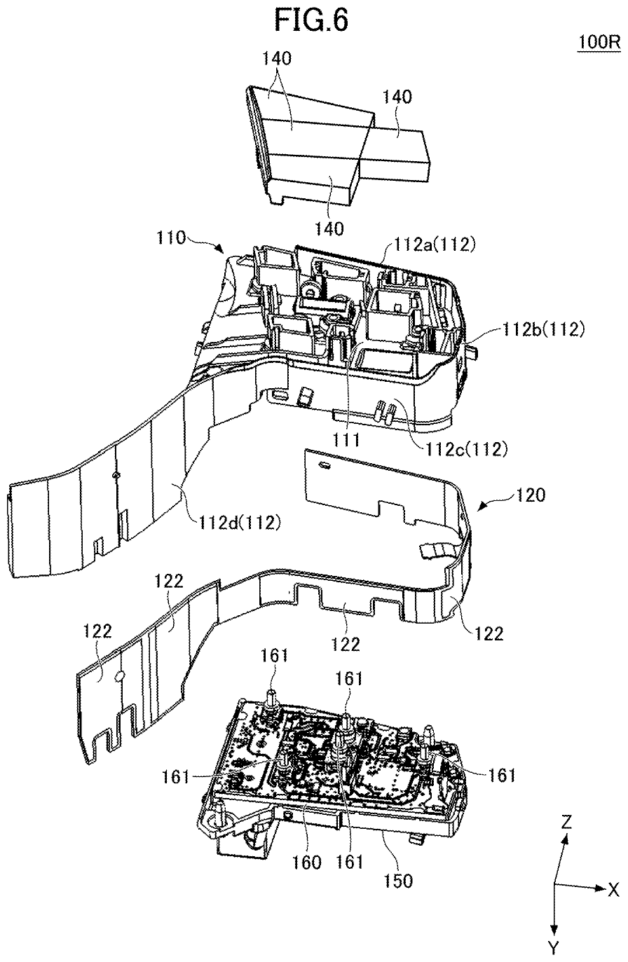

Hereinafter, the configuration of the sensor device 100 will be described using the sensor device 100R as a representative example. FIG. 5 is an external perspective view of the sensor device 100R according to the present embodiment. FIG. 6 is an exploded perspective view of the sensor device 100R according to the present embodiment.

As illustrated in FIGS. 2, 5, and 6, the sensor device 100R includes a housing 110, an electrostatic detector 120, the plurality of operation knobs 140, a bottom case 150, and a substrate 160.

The housing 110 is a resin-made, container-shaped member that is thin in the longitudinal direction (Y-axis direction) and has an interior space. The housing 110 has a substantially rectangular shape in a plan view from the driver side (negative Y-axis side). The housing 110 includes a driver-facing wall portion 111 that extends so as to face the driver, and an outer peripheral wall portion 112 that extends toward the driver.

The driver-facing wall portion 111 defines a surface facing the driver, with the decorative cover 16 interposed therebetween. The driver-facing wall portion 111 has a substantially flat plate shape parallel to the substrate 160 and closes off the driver side (negative Y-axis side) of the interior space of the housing 110 relative to the substrate 160.

The outer peripheral wall portion 112 surrounds the periphery of the interior space of the housing 110. As illustrated in FIG. 6, the outer peripheral wall portion 112 of the housing 110 includes an upper wall portion 112a, a right wall portion 112b, and a lower wall portion 112c provided so as to surround the upper side (positive Z-axis side), the right side (positive X-axis side), and the lower side (negative Z-axis side) of the driver-facing wall portion 111. Parts of the upper wall portion 112a, the right wall portion 112b, and the lower wall portion 112c are provided so as to project from the surface of the driver-facing wall portion 111 of the housing 110 to the driver side (negative Y-axis side).

The outer peripheral wall portion 112 of the housing 110 includes an extended wall portion 112d provided so as to extend the outer peripheral wall portion 112. The extended wall portion 112d is a wall-like portion extending obliquely downward (negative X-axis direction and negative Z-axis direction) from the left end of the lower wall portion 112c of the outer peripheral wall portion 112 along the right side surface of the third portion 14C of the spoke portion 14 (see FIG. 1).

In the interior space of the housing 110, the substrate 160 and its associated components (switch elements 161 provided on the substrate 160, actuators that link the operation knobs 140 to the switch elements 161, and other related parts) are arranged for the plurality of switches.

The electrostatic detector 120 is a sheet-like sensor provided for detecting, in a non-contact manner, gripping of the grip portion 13R on the right side of the rim portion 13 by the driver's right hand by an electrostatic method. The electrostatic detector 120 has a strip-like shape as a whole. The electrostatic detector 120 is provided on the outer peripheral wall portion 112 of the housing 110.

Specifically, the electrostatic detector 120 is attached along the surfaces of the upper wall portion 112a, the right wall portion 112b, the lower wall portion 112c, and the extended wall portion 112d of the outer peripheral wall portion 112 of the housing 110 by a double-sided tape or the like. Thus, the electrostatic detector 120 is arranged to face the grip portion 13R of the rim portion 13 provided on the right side (in the positive direction of the X-axis) of the housing 110, and the fingers of the driver's right hand engaging the grip portion 13R can be detected in a non-contact manner.

Although the configuration of the sensor device 100R has been described above, the configuration of the sensor device 100L is substantially symmetrical to the configuration of the sensor device 100R, and is essentially the same as the configuration of the sensor device 100R.

The plurality of operation knobs 140 are arranged so as to be aligned with the driver-facing wall portion 111 of the housing 110 in an operable manner. The surfaces of the plurality of operation knobs 140 are exposed through the opening 16A of the decorative cover 16 and serve as the operation surface 100A through which the driver inputs various operations. Each of the plurality of operation knobs 140 is supported by the housing 110 so that the operation surface 100A faces the driver. Each of the plurality of operation knobs 140 is movably supported by the housing 110 so as to pass through the driver-facing wall portion 111. When the driver inputs an operation, the switch element 161 provided on the substrate 160 is actuated via an actuator or the like.

The bottom case 150 is a member made of a resin for closing off the bottom surface side (positive Y-axis side) of the interior space of the housing 110. The bottom case 150 is detachably provided to the housing 110 by screwing or the like.

The substrate 160 is a member made of a resin and having a flat shape, provided in the interior space of the housing 110 and supported by the bottom case 150. The plurality of switch elements 161 are provided on the substrate 160 corresponding to the plurality of operation knobs 140. The switch element 161 is a push switch as an example of an “operation input detector”, and in the present embodiment, detects a pressing operation input via the operation knobs 140 by the driver. In the present embodiment, the bottom case 150 is a separate component from the housing 110, but the bottom case 150 and the housing 110 may be integrally formed.

### Stack Structure of Electrostatic Detector 120

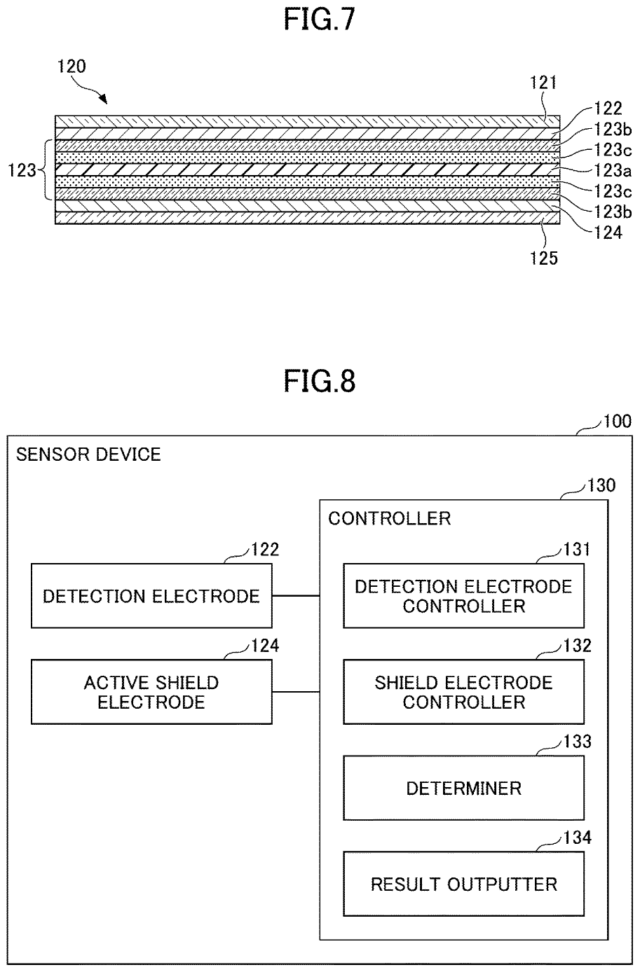

FIG. 7 is a cross-sectional view schematically illustrating a stack structure of the electrostatic detector 120 included in the sensor device 100 according to the present embodiment. As illustrated in FIG. 7, the electrostatic detector 120 has a stack structure in which a coverlay 121, a detection electrode 122, a base 123, an active shield electrode 124, and a coverlay 125 are stacked in order from the surface side.

The base 123 is a flexible and insulating sheet-like member serving as a base of the electrostatic detector 120. In the example illustrated in FIG. 7, the base 123 has a structure in which a polyimide film 123b is attached to the front and rear surfaces of an intermediate material 123a, such as silicon rubber, with a double-sided tape 123c, respectively.

The detection electrode 122 is formed on the front surface of the base 123. The detection electrode 122 is capacitively coupled with the fingers of the driver's hand adjacent to the detection electrode, and is provided for non-contact detection of a grip by the fingers of the driver's hand by an electrostatic capacitance method.

The active shield electrode 124 is formed on the rear surface of the base 123. The active shield electrode 124 is driven by a drive signal synchronized with a drive signal of the detection electrode 122, so that noise components applied to the detection electrode 122 from the rear side of the detection electrode 122 can be removed.

A thin-film conductor such as ITO (indium tin oxide), IZO (indium zinc oxide), or a metal film (e.g. composite materials of silver, copper, aluminum and molybdenum) is used as the detection electrode 122 and the active shield electrode 124.

The coverlay 121 is a resin-made, film-shaped member stacked on the front surface of the base 123 in a state where the detection electrode 122 is formed on the front surface of the base 123. The coverlay 121 covers the front surface of the base 123, thereby protecting the front surface of the base 123 and the detection electrode 122.

The coverlay 125 is a resin-made, film-shaped member stacked on the rear surface of the base 123 in a state where the active shield electrode 124 is formed on the rear surface of the base 123. The coverlay 125 covers the rear surface of the base 123, thereby protecting the rear surface of the base 123 and the active shield electrode 124.

The electrostatic detector 120 having a stack structure as described above is attached, at the rear surface of the electrostatic detector 120 (the surface on which the coverlay 125 is stacked), to the front surface of the outer peripheral wall portion 112 (upper wall portion 112a, right wall portion 112b, lower wall portion 112c, and extended wall portion 112d) of the housing 110. Thus, the electrostatic detector 120 is provided in such a manner that the detection electrode 122 and the active shield electrode 124 are arranged in the spoke portion 14 of the steering wheel 12 so as to be opposed to the grip portion 13R of the rim portion 13. Thus, the electrostatic detector 120 is capacitively coupled with the fingers of the driver's hand engaging the grip portion 13R, and a change in capacitance due to the grip can be detected by the detection electrode 122 in a non-contact manner. At this time, the electrostatic detector 120 can remove noise components applied to the detection electrode 122 from the housing 110 side, which is the rear side of the electrostatic detector 120 by the active shield electrode 124.

### Configuration of Control System Included in Sensor Device 100

FIG. 8 is a diagram illustrating a configuration of a control system included in the sensor device 100 according to the present embodiment. As illustrated in FIG. 8, the control system included in the sensor device 100 includes the detection electrode 122 and the active shield electrode 124 described above, and a control device 130. The configuration of the control system of the sensor device 100 illustrated in FIG. 8 is a configuration common to the sensor devices 100L and 100R.

The control device 130 is a device capable of determining the presence or absence of the fingers of the driver's hand engaging the rim portion 13 (grip portion 13L or 13R) of the steering wheel 12 based on the detection result by the detection electrode 122, and outputting the determination result.

As illustrated in FIG. 8, the control device 130 is electrically connected to each of the detection electrode 122 and the active shield electrode 124. The control device 130 includes a detection electrode controller 131, a shield electrode controller 132, a determiner 133, and a result outputter 134.

The detection electrode controller 131 detects a change in capacitance at the detection electrode 122. Specifically, the detection electrode controller 131 drives the detection electrode 122 by applying an AC voltage consisting of a sine wave to the detection electrode 122 as a drive signal. The detection electrode 122 detects a change in the current value of the current flowing through the detection electrode 122 as a change in capacitance.

For example, the detection electrode 122 of the sensor device 100R is provided in the vicinity of the grip portion 13R so as to face the grip portion 13R. For this reason, when the fingers of the driver's right hand engage the grip portion 13R, the fingers of the driver's right hand are present in the vicinity of the detection electrode 122 of the sensor device 100R. Thus, the detection electrode 122 of the sensor device 100R is capacitively coupled with the fingers of the driver's right hand, and the current value of the current flowing through the detection electrode 122 changes. Thus, the detection electrode 122 of the sensor device 100R can detect the fingers of the driver's right hand (non-contact detection).

As illustrated in FIGS. 5 and 6, since the electrostatic detector 120 of the sensor device 100R has a shape bent substantially at a right angle at the upper right corner portion of the housing 110 and the lower right corner portion of the housing 110, the fingers of the driver's right hand can be detected within a range of approximately ±30° in the grip portion 13R with the 90° position of the rim portion 13 (positive X-axis side) as a reference.

The shield electrode controller 132 generates an active shield signal and outputs the active shield signal to the active shield electrode 124. Thus, the shield electrode controller 132 drives the active shield electrode 124. The active shield signal is, for example, a signal (i.e., AC voltage consisting of a sine wave) having a waveform synchronized with a drive signal applied from the detection electrode controller 131 to the detection electrode 122. By being driven, the active shield electrode 124 can remove noise components applied to the detection electrode 122 from the rear side of the active shield electrode 124 (the housing 110 side). In other words, the active shield electrode 124 can remove noise components from a capacitance detected by the detection electrode 122.

The determiner 133 determines the presence or absence of the fingers of the driver's hand engaging the grip portion 13L or 13R based on a change in a capacitance of the detection electrode 122 detected by the detection electrode controller 131.

For example, the determiner 133 determines presence of the fingers of the driver's right hand engaging the grip portion 13R when a difference between a reference value and a capacitance value of the detection electrode 122 included in the sensor device 100R is equal to or greater than a predetermined threshold value th.

On the other hand, the determiner 133 determines absence of the fingers of the driver's right hand engaging the grip portion 13R when a difference between a reference value and a capacitance value of the detection electrode 122 included in the sensor device 100R is less than the predetermined threshold value th.

The reference value is set based on the assumption that the capacitance corresponds to a state in which the driver's fingers, or any other objects, are not near the grip portions 13L or 13R.

A suitable value obtained in advance by an actual machine test, simulation, or the like is used for the threshold value th. As described above, since the control device 130 drives the active shield electrode 124, a capacitance detected by the detection electrode 122 is a value obtained by removing noise components from the rear side of the detection electrode 122 (the housing 110 side). For this reason, in the present embodiment, since a value obtained by removing noise components from the rear side of the detection electrode 122 (the housing 110 side) by the active shield electrode 124 is used as the threshold value th, the value is lower than that in a conventional configuration in which the active shield electrode is not used.

The result outputter 134 outputs the determination result (i.e., the presence or absence of the driver's fingers engaging the grip portion 13L or 13R) by the determiner 133 to the outside (for example, a device that performs processing according to the result of determination by the determiner 133).

The control device 130 is implemented by, for example, a processor (for example, CPU (central processing unit)), a storage medium (for example, ROM (read only memory), RAM (random access memory), SSD (solid state drive), etc.), and a computer (for example, integrated circuits (ICs)) having an external interface or the like. For example, control processing in each functional unit of the control device 130 illustrated in FIG. 8 is implemented by the processor executing a program stored in the storage medium in the control device 130.

### Water Prevention Structure of Housing 110

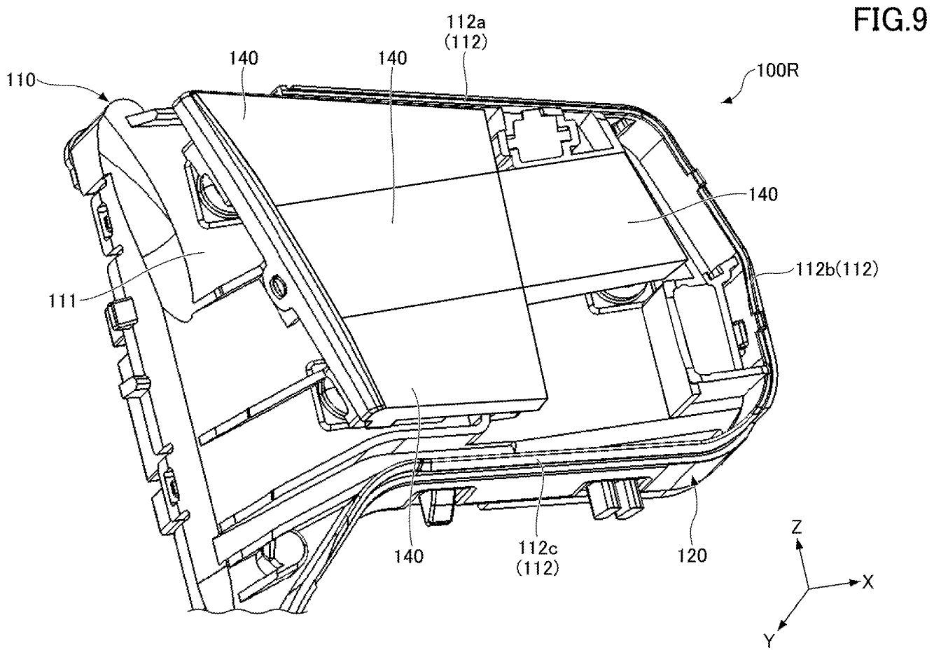

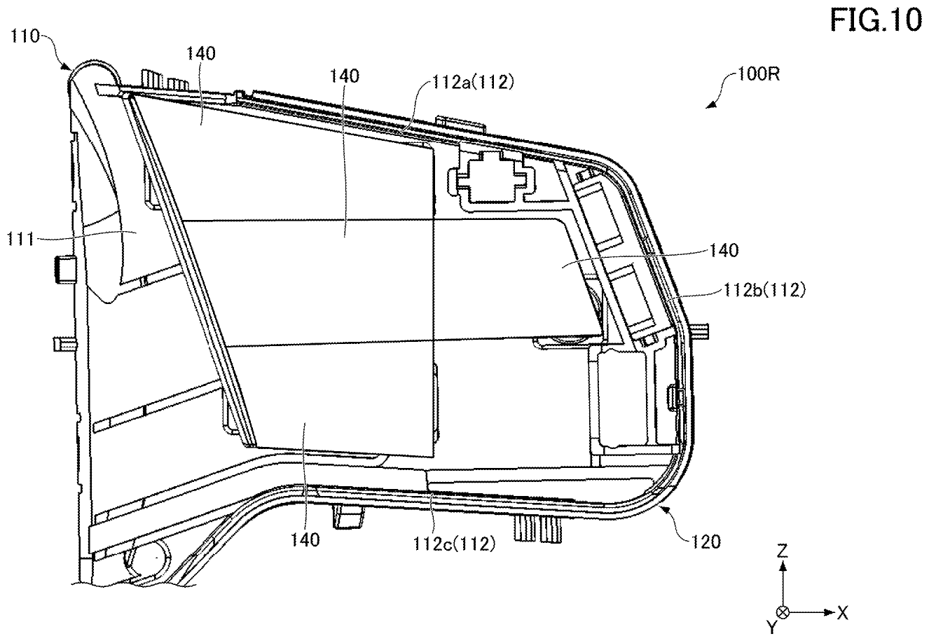

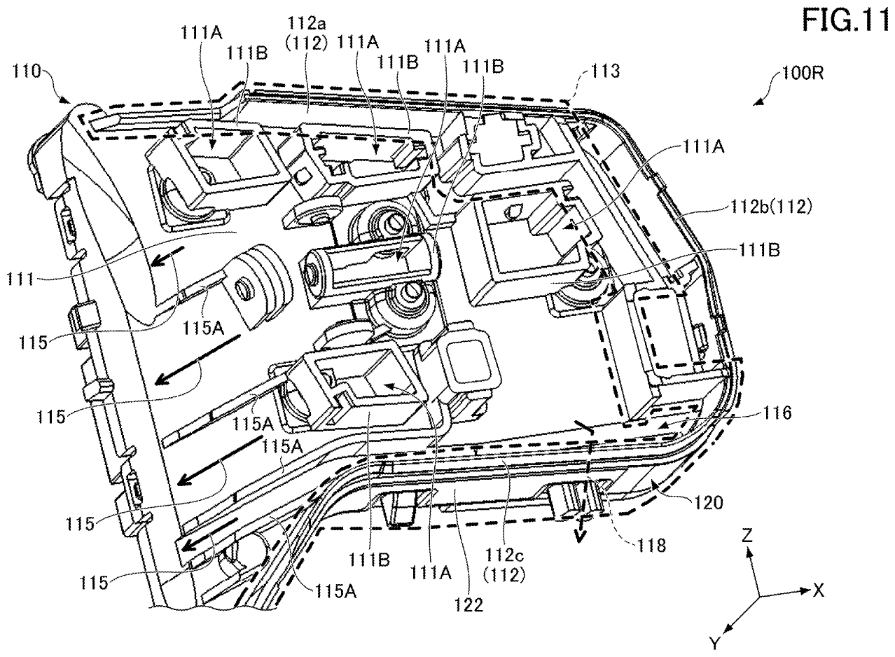

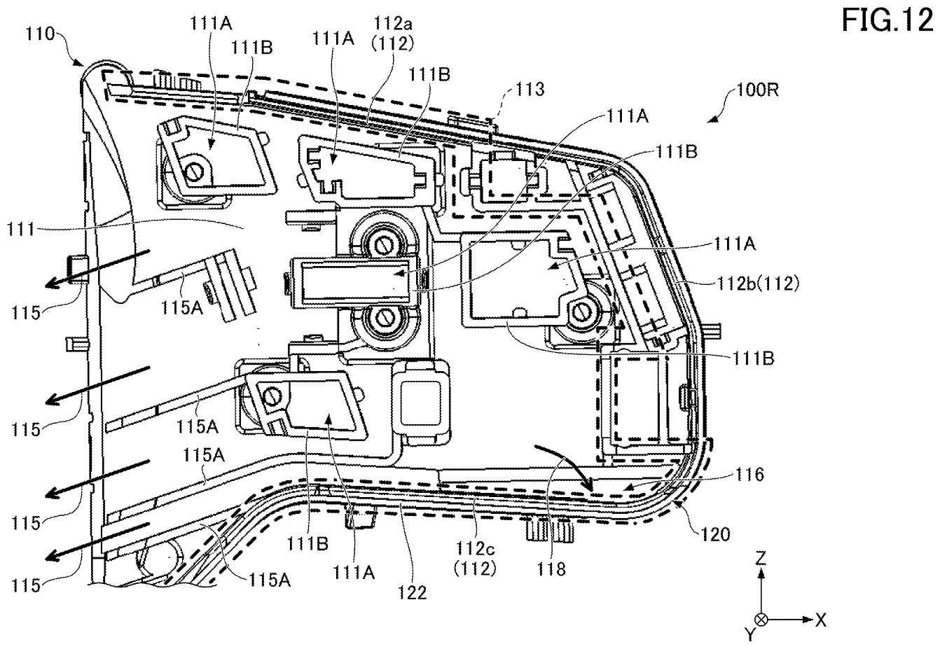

FIG. 9 is a partially enlarged perspective view of the sensor device 100R according to the present embodiment. FIG. 10 is a plan view of the sensor device 100R according to the present embodiment as seen from the driver side. FIG. 11 is a partially enlarged perspective view of the sensor device 100R according to the present embodiment, shown with the plurality of operation knobs 140 removed. FIG. 12 is a plan view of the sensor device 100R according to the present embodiment as seen from the driver side, shown with the plurality of operation knobs 140 removed.

In the sensor device 100R according to the present embodiment, the housing 110 includes a regulating wall (e.g., the driver-facing wall portion 111, described later) configured to prevent water, when the sensor device 100R is exposed to water, from reaching the detection electrode 122 or the substrate 160. Specifically, the regulating wall controls water that has entered from the periphery of the operation knobs 140 through the opening 16A of the decorative cover 16, in both a case where the steering wheel 12 is in an initial state and a case where the steering wheel 12 is rotated in any direction.

With the regulating wall, when the sensor device 100R is exposed to water, the sensor device 100R according to the present embodiment can prevent water from reaching the detection electrode 122 and the substrate 160 by controlling its flow, thereby preventing these components from becoming wet, regardless of the rotational state of the steering wheel 12. Accordingly, in the sensor device 100R of the present embodiment, even under water exposure, the detection electrode 122 can reliably detect the gripping state, and the substrate 160 can reliably detect operation input via the operation knobs 140.

As illustrated in FIGS. 9 through 12, in the sensor device 100R according to the present embodiment, the housing 110 includes the driver-facing wall portion 111. The driver-facing wall portion 111 is an example of a first regulating wall included in the regulating wall. The driver-facing wall portion 111 is provided on the driver side in parallel with the substrate 160 in the interior space of the housing 110. In other words, the driver-facing wall portion 111 is a wall having a flat-plate shape that covers the driver side and closes off the opening of the interior space so that water does not flow from the driver side to the substrate 160 into the interior space of the housing 110.

With the driver-facing wall portion 111, the sensor device 100R according to the present embodiment can prevent water that has entered from the periphery of the operation knobs 140 in the opening 16A of the decorative cover 16 from entering into the interior space of the housing 110, thereby preventing the substrate 160 provided inside the housing 110 from being exposed to water.

Herein, as illustrated in FIGS. 2, 11, and 12, the driver-facing wall portion 111 is formed with a plurality of through-holes 111A. Each of the plurality of through-holes 111A is provided for vertically movably supporting the operation knobs 140, inserting the operation knob 140 and an actuator (not illustrated) into the interior space of the housing 110, and pressing the switch element 161 provided on the substrate 160 by the actuator in accordance with the operation input via the operation knobs 140.

Each of the plurality of through-holes 111A includes a cylindrical wall portion 111B surrounding the through-hole 111A. The through-holes 111A and the wall portion 111B are entirely covered by the operation knobs 140 (in other words, provided inside the outer periphery of the operation knobs 140) when viewed from the driver side, and the wall portion 111B is provided so as to project toward the driver side from the surface of the driver-facing wall portion 111. Thus, the wall portion 111B can prevent water that has entered from the periphery of the operation knobs 140 in the opening 16A and has reached the surface of the driver-facing wall portion 111 from entering the interior space of the housing 110 through the through-holes 111A, thereby preventing the substrate 160 provided in the interior space of the housing 110 from being exposed to water.

As illustrated in FIGS. 2, 11, and 12, in the sensor device 100R according to the present embodiment, the housing 110 includes a second regulating wall 113 erected on the driver-facing wall portion 111 (first regulating wall) toward the driver side between the operation knobs 140 and the detection electrode 122 (electrostatic detector 120). The second regulating wall 113 is an example of a second regulating wall included in the regulating wall. The second regulating wall 113 controls the flow of water toward the detection electrode 122 (electrostatic detector 120), thereby preventing water from reaching the detection electrode 122. The second regulating wall 113 is continuously provided between the opening 16A and the detection electrode 122 (electrostatic detector 120).

With the second regulating wall 113, the sensor device 100R according to the present embodiment can confine water that has entered from the periphery of the operation knobs 140 in the opening 16A and has reached the surface of the driver-facing wall portion 111 to the region inside the second regulating wall 113, thereby preventing water from flowing outward beyond the second regulating wall 113. Consequently, the detection electrode 122 provided outside the second regulating wall 113 can be reliably protected from exposure to water.

In particular, the second regulating wall 113 (see the area surrounded by the dashed lines in FIGS. 11 and 12) is continuously provided along the detection electrode 122 (electrostatic detector 120) without an interruption partway through. In other words, the electrostatic detector 120 is provided along the outer peripheral wall portion 112 (upper wall portion 112a, right wall portion 112b, lower wall portion 112c, and extended wall portion 112d) of the housing 110, and the second regulating wall 113 is provided substantially along the outer peripheral wall portion 112 of the housing 110.

With the second regulating wall 113, the sensor device 100R according to the present embodiment can reliably prevent water that has entered from the periphery of the operation knobs 140 in the opening 16A and has reached the region inside the second regulating wall 113 on the surface of the driver-facing wall portion 111 from flowing into the region outside the second regulating wall 113, thereby reliably preventing the detection electrode 122 provided in the region outside the second regulating wall 113 from being exposed to water.

Furthermore, the second regulating wall 113 is provided so as to surround the driver-facing wall portion 111 in three directions (i.e., the positive Z-axis direction, the negative Z-axis direction, and the positive X-axis direction) when the steering wheel 12 in which the electrostatic detector 120 is provided is viewed in a plan from the driver side) without an interruption partway through. For this reason, the second regulating wall 113 can control the flow of water flowing on the surface of the driver-facing wall portion 111 due to gravity at the position of the second regulating wall 113 when the surface of the driver-facing wall portion 111 is exposed to water in both a case where the steering wheel 12 is in an initial state and a case where the steering wheel 12 is rotated in any direction. The second regulating wall 113 can thereby reliably prevent the electrostatic detector 120 from being exposed to water.

In the present embodiment, the second regulating wall 113 includes a part of the upper wall portion 112a of the outer peripheral wall portion 112 and a part of the lower wall portion 112c of the outer peripheral wall portion 112. However, the second regulating wall 113 may include only the outer peripheral wall portion 112, or may be provided separately from the outer peripheral wall portion 112 without including the outer peripheral wall portion 112. In other words, the second regulating wall 113 need not necessarily be adjacent to the outer peripheral wall portion 112, and may be provided in a freely chosen region between the operation knobs 140 and the detection electrode 122 to prevent the detection electrode 122 from being exposed to water.

In the sensor device 100R according to the present embodiment, the housing 110 includes one or more drainage paths (e.g., a first drainage path 115 and a second drainage path 118) for discharging water, when the sensor device 100R is exposed to water, that has entered from the periphery of the operation knobs 140, in a direction where the detection electrode 122 and the substrate 160 are not located.

With the drainage path, the sensor device 100R according to the present embodiment can guide water that has reached the driver-facing wall portion 111, in a direction where the detection electrode 122 and the substrate 160 are not located, thereby discharging water outside the sensor device 100R. For this reason, the sensor device 100R according to the present embodiment can suppress the retention of water in the device, and prevent water from capacitively coupling with the detection electrode 122, thereby preventing erroneous detection of the driver's grip.

Herein, as illustrated by the arrows in FIGS. 11 and 12, the drainage path of the housing 110 includes the first drainage path 115 and the second drainage path 118, as an example.

Here, as illustrated in FIGS. 11 and 12, in the sensor device 100R according to the present embodiment, the drainage path of the housing 110 includes the first drainage paths 115 extending from the periphery of the operation knobs 140 toward the hub portion 15 (see FIG. 1).

With the first drainage paths 115, when the sensor device 100R is exposed to water, the sensor device 100R according to the present embodiment can easily discharge water that has entered from the periphery of the operation knobs 140 in the direction of the hub portion 15 (in other words, the direction of the center of the steering wheel 12, which is the direction in which the detection electrodes 122 and the substrate 160 are not present).

In particular, in the sensor device 100R according to the present embodiment, the first drainage paths 115 include a plurality of ribs 115A inclinedly extending toward the hub portion 15 and in the direction of gravity when the steering wheel 12 is in an initial state. Each of the plurality of ribs 115A has a wall-like shape protruding from the surface of the driver-facing wall portion 111 toward the driver.

With the ribs 115A, the sensor device 100R according to the present embodiment can reduce the flow velocity of water that has entered from the periphery of the operation knobs 140 and brought into contact with the ribs 115A in the direction of gravity, and divide the water into small streams, thereby reliably discharging water that has entered from the periphery of the operation knobs 140 toward the hub portion 15 (i.e., the center of the steering wheel 12).

As illustrated in FIGS. 11 and 12, in the sensor device 100R according to the present embodiment, the housing 110 includes a through-hole 116 penetrating the housing 110 from the driver side toward the back surface side in a region in the vicinity of the connection portion 17 (see FIGS. 1, 3, and 4) between the spoke portion 14 and the rim portion 13. In the sensor device 100R according to the present embodiment, the housing 110 includes the second drainage path 118 for discharging water that has entered from the periphery of the operation knobs 140 toward the back surface side of the housing 110 via the through-hole 116.

Specifically, the through-hole 116 is provided at a lower right corner of the driver-facing wall portion 111 in a region not overlapping with the substrate 160 as seen from the driver. In other words, the through-hole 116 is provided so as to penetrate a region between the substrate 160 and the detection electrode 122 of the housing 110. On the other hand, the lower wall portion 112c of the housing 110 is inclined downward to the right with respect to a horizontal plane horizontal to the ground (a horizontal plane parallel to the X-axis) when the steering device 10 is in a neutral steering position. For this reason, water that has entered from the periphery of the operation knobs 140 and has reached the surface of the driver-facing wall portion 111 flows in the direction of the lower wall portion 112c due to gravity, and further flows along the lower wall portion 112c toward the through-hole 116 provided at the most downstream (i.e., the most downstream flow in the direction of gravity) of the second drainage path 118.

With this structure, when the sensor device 100R is exposed to water, the sensor device 100R according to the present embodiment can cause water that has entered from the periphery of the operation knobs 140 to flow downstream of the second drainage path 118 due to gravity on the surface of the driver-facing wall portion 111. Then, the sensor device 100R according to the present embodiment can discharge water flowing downstream of the second drainage path 118 due to gravity from the through-hole 116 formed at the most downstream of the second drainage path 118 to the back surface side (positive Y-axis side) of the housing 110 without contacting both the substrate 160 and the detection electrode 122.

Since the sensor device 100R according to the present embodiment includes the outer peripheral wall portions 112 in the three directions of the driver-facing wall portion 111, depending on the rotational state of the steering wheel 12, when the sensor device 100R is exposed to water, water that has entered from the periphery of the operation knobs 140 is received from the three directions by the outer peripheral wall portions 112 and may accumulate in the lower right corner of the driver-facing wall portion 111, which is the lower corner in the direction of gravity (see FIG. 14). However, in the sensor device 100R according to the present embodiment, since the housing 110 includes the through-hole 116 in the lower right corner of the driver-facing wall portion 111, water that has entered from the periphery of the operation knobs 140 can be discharged from the through-hole 116 to the back surface side (positive Y-axis side) of the housing 110, thereby preventing water from accumulating in the lower right corner of the driver-facing wall portion 111 regardless of the rotational state of the steering wheel 12.

For example, when water flowing through the second drainage path 118 remains in the inner wall of the through-hole 116 or in the vicinity of the through-hole 116, water and the detection electrode 122 are capacitively coupled, and there is a possibility that noise components are included in a capacitance detected by the detection electrode 122.

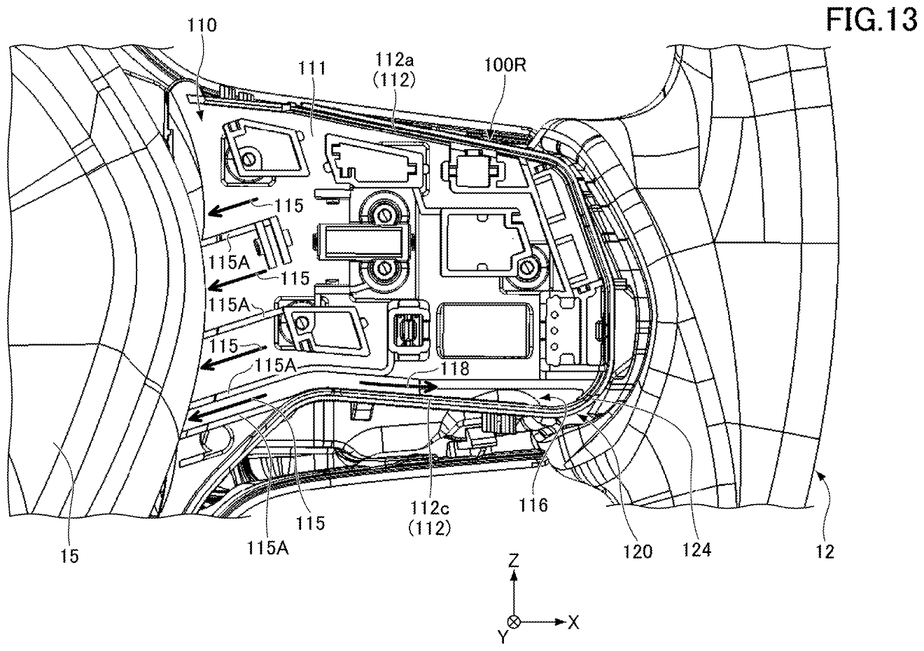

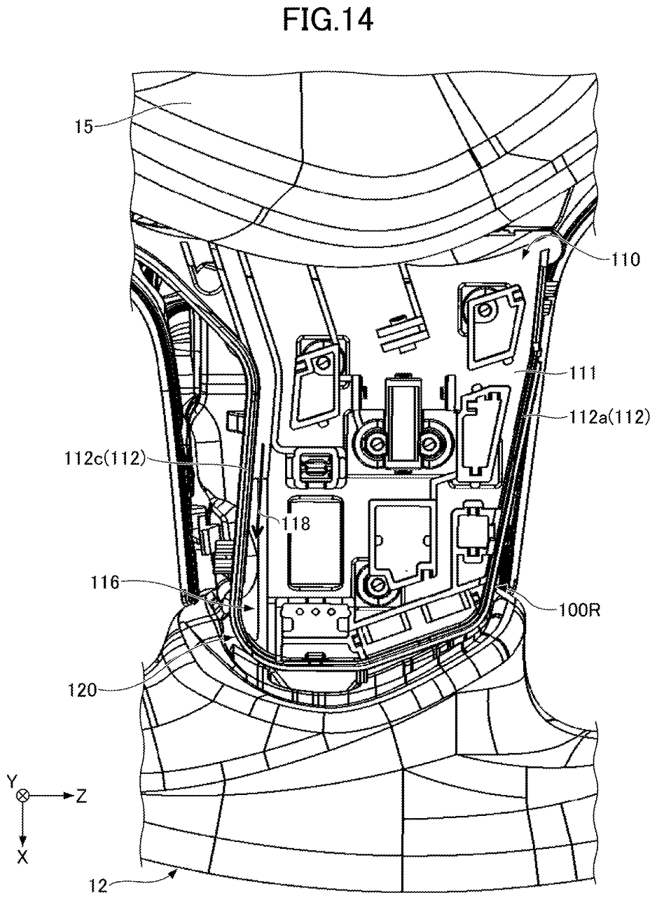

Therefore, the sensor device 100R according to the present embodiment is provided with the active shield electrode 124 (see FIGS. 7 and 13) provided in a region in the vicinity of the through-hole 116 on the outer peripheral surface of the housing 110.

With the active shield electrode 124, the sensor device 100R according to the present embodiment can shield capacitive coupling of water to the detection electrode 122, even when water remains within the inner wall or in the vicinity of the through-hole 116.

### Drainage Effect by Sensor Device 100R

FIG. 13 is a diagram illustrating a drainage path in the sensor device 100R when the steering wheel 12 is in an initial state. As illustrated in FIG. 13, when the sensor device 100R is exposed to water when the steering wheel 12 is in an initial state, water from the periphery of the operation knobs 140 according to gravity are received by the plurality of ribs 115A and the lower wall portion 112c of the outer peripheral wall portion 112, which are positioned in the lower side of the direction of gravity (Z-axis direction), and water is discharged, in the direction of the hub portion 15 (i.e., the direction toward the center of the steering wheel 12, where neither the detection electrode 122 nor the substrate 160 is present), through a plurality of first drainage paths 115 provided along the plurality of ribs 115A, and water is discharged from the through-hole 116 to the back surface side (positive Y-axis side) of the housing 110 through the second drainage path 118 provided along the lower wall portion 112c, without the water reaching the detection electrode 122 and the substrate 160.

FIG. 14 is a diagram illustrating a drainage path in the sensor device 100R when the steering wheel 12 is rotated 90 degrees clockwise. As illustrated in FIG. 14, when the sensor device 100R is exposed to water when the steering wheel 12 is rotated 90 degrees clockwise, water that has entered from the periphery of the operation knobs 140 due to gravity can be discharged from the through-hole 116 on the lower side in the direction of gravity (X-axis direction) to the back surface side (positive Y-axis side) of the housing 110, through the second drainage path 118 extending in the direction of gravity (X-axis direction) along the lower wall portion 112c of the outer peripheral wall portion 112, without the water reaching the detection electrode 122 and the substrate 160.

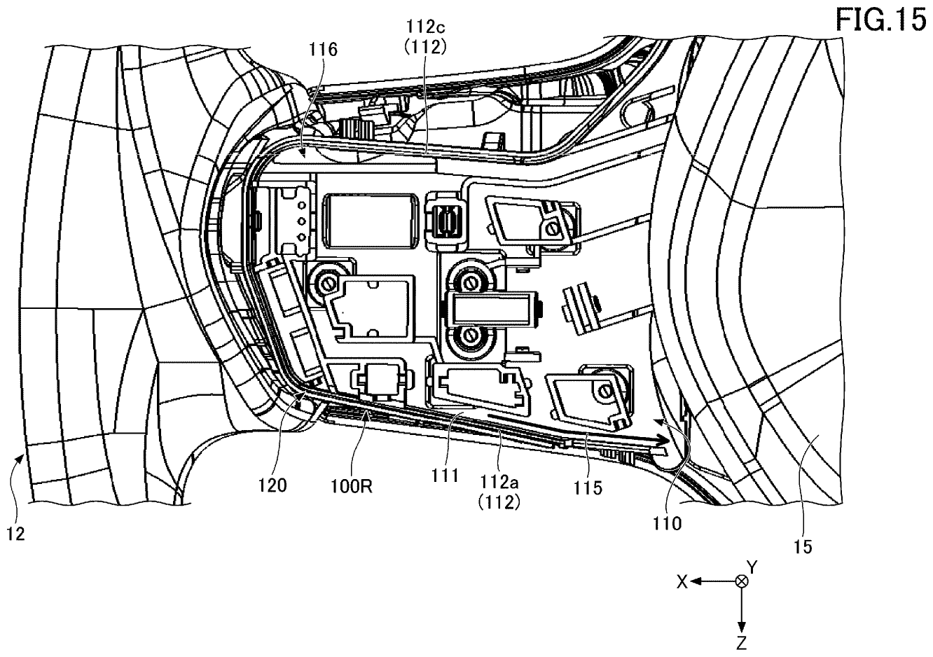

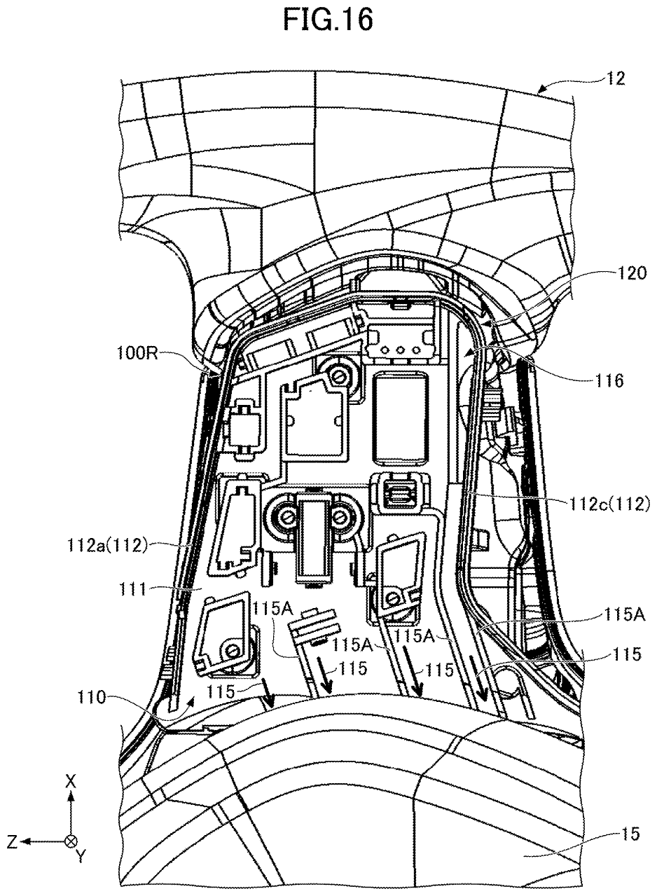

FIG. 15 is a diagram illustrating a drainage path in the sensor device 100R when the steering wheel 12 is rotated 180 degrees clockwise. As illustrated in FIG. 15, when the sensor device 100R is exposed to water when the steering wheel 12 is rotated 180 degrees clockwise, water that has entered from the periphery of the operation knobs 140 can be received by the upper wall portion 112a of the outer peripheral wall portion 112 according to gravity, which is positioned in the lower side of the direction of gravity (Z-axis direction), and the water is discharged in the direction of the hub portion 15 (i.e., the direction toward the center of the steering wheel 12, where neither the detection electrode 122 nor the substrate 160 is present) through the first drainage path 115 provided along the upper wall portion 112a.
FIG. 16 is a diagram illustrating a drainage path in the sensor device 100R when the steering wheel 12 is rotated 270 degrees clockwise. As illustrated in FIG. 16, when the sensor device 100R is exposed to water when the steering wheel 12 is rotated 270 degrees clockwise, water that has entered from the periphery of the operation knobs 140 can be discharged according to gravity in the direction of the hub portion 15 (i.e., the direction toward the center of the steering wheel 12, where neither the detection electrode 122 nor the substrate 160 is present), which is positioned in the lower side of the direction of gravity (X-axis direction) through a plurality of first drainage paths 115 extending in the direction of gravity (X-axis direction) along the plurality of ribs 115A.

As described above, when the sensor device 100R is exposed to water, the sensor device 100R according to the present embodiment can reliably discharge water that has entered from the periphery of the operation knobs 140 to the outside of the sensor device 100R through the first drainage path 115, the second drainage path 118, and the through-hole 116, regardless of a rotational state of the steering wheel 12, and can prevent the detection electrode 122 and the substrate 160 from becoming wet.

Although one embodiment of the present invention has been described in detail above, the present invention is not limited to these embodiments, and various alterations and changes are possible within the scope of the present invention described in the appended claims.

What is claimed is:

1. A sensor device to be mounted in a spoke portion of a steering wheel and to be covered by a decorative cover having an opening, the steering wheel including a rim portion for a driver to grip, a hub portion arranged at a center of the rim portion, and the spoke portion extending from the hub portion and supporting the rim portion, the sensor device comprising:
a housing;
a detection electrode provided on an outer peripheral surface of the housing so as to face the rim portion and configured to detect a capacitance by being capacitively coupled with a hand of the driver gripping the rim portion;
an operation knob having an operation surface exposed through the opening of the decorative cover and arranged in such a manner that the operation surface faces the driver;
a substrate provided in an interior space of the housing; and
an operation input detector provided on the substrate and configured to detect an operation input by the driver via the operation knob, wherein
the housing includes a regulating wall configured to control, when the sensor device is exposed to water, water that has entered from the periphery of the operation knob in the opening of the decorative cover so as not to reach the detection electrode and the substrate in both a case where the steering wheel is in an initial state and a case where the steering wheel is rotated in any direction.

2. The sensor device according to claim 1, wherein
the regulating wall includes
a first regulating wall provided so as to close off a driver side of the interior space of the housing relative to the substrate, the first regulating wall defining a driver-facing surface; and
a second regulating wall erected on the first regulating wall toward the driver side between the operation knob and the detection electrode.

3. The sensor device according to claim 2, wherein
the second regulating wall is provided continuously along the detection electrode without an interruption partway through.

4. The sensor device according to claim 3, wherein
the housing includes a drainage path for discharging water, when the sensor device is exposed to water, that has entered from the periphery of the operation knob in the opening of the decorative cover, in a direction where the detection electrode and the substrate are not located.

5. The sensor device according to claim 4, wherein
the drainage path includes a first drainage path extending from the periphery of the operation knob toward the hub portion.

6. The sensor device according to claim 5, wherein
the first drainage path includes a rib inclined toward the hub portion and toward a direction of gravity when the steering wheel is in the initial state.

7. The sensor device according to claim 4, wherein
the housing includes a through-hole penetrating the housing from the driver side to a back surface side in a region in the vicinity of a connection portion between the spoke portion and the rim portion, and
the drainage path includes a second drainage path for discharging water that has entered from the periphery of the operation knob in the opening of the decorative cover to the back surface side of the housing via the through-hole.

8. The sensor device according to claim 7, further comprising an active shield electrode provided in a region in the vicinity of the through-hole in the outer peripheral surface of the housing.

9. The sensor device according to claim 1, further comprising a determiner configured to determine whether the driver grips the rim portion based on a change in the capacitance detected by the detection electrode.

10. A steering device comprising:
the steering wheel; and
the sensor device according to claim 1 mounted in the steering wheel.
